(19) United States
(12) Patent Application Publication
(10) Pub. No.: US 2024/0328714 A1
(43) Pub. Date: Oct. 3, 2024

(54) FURNACE TUBE STRUCTURE, FURNACE REAR SEALING DEVICE, AND FURNACE

(71) Applicant: LAPLACE Renewable Energy Technology Co., Ltd., Shenzhen (CN)

(72) Inventors: Tairong Zhu, Shenzhen (CN); Yang Xiao, Shenzhen (CN); Shu Yi, Shenzhen (CN); Jiaji Lin, Shenzhen (CN)

(21) Appl. No.: 18/738,008

(22) Filed: Jun. 8, 2024

(30) Foreign Application Priority Data
May 12, 2023 (CN) 202321481569.5
Jun. 12, 2023 (CN) 202321481566.1

(51) Int. Cl. F27B 5/04; C23C 16/455; F27B 5/06; F27D 7/06; F27D 9/00

(52) U.S. Cl. CPC F27B 5/04; C23C 16/45517; F27B 5/06; F27D 7/06; F27D 9/00; F27D 2007/066; F27D 2009/0013

(57) ABSTRACT

A furnace tube structure, a furnace rear sealing device, and a furnace are provided. The furnace includes a furnace body, a furnace tube, a flange mounting plate, a furnace rear flange, and a rear cover. The furnace tube is arranged in the furnace body. The flange mounting plate is arranged on a rear end of the furnace body. The furnace rear flange is mounted on the flange mounting plate. The rear cover is connected to the furnace rear flange and configured to seal the rear end of the furnace body, the rear cover is provided with an air pipe that communicates with the furnace tube.

### CROSS-REFERENCE TO RELATED APPLICATIONS

This application claims priority to Chinese Patent Application No. 202321481566.1 filed on Jun. 12, 2023 and Chinese Patent Application No. 202321481569.5 filed on Jun. 12, 2023 in China State Intellectual Property Administration, the contents of which are incorporated by reference herein.

### TECHNICAL FIELD

The present disclosure relates to the field of semiconductor manufacturing equipment technologies, in particular to a furnace tube structure, a furnace rear sealing device, and a furnace.

### BACKGROUND

A semiconductor manufacturing equipment is normally provided for the processing and manufacturing process of photovoltaic cells. As shown in FIG. 1, a boron diffusion furnace tube used in the related art has a furnace tube flange welded at a front end, a closed semicircular quartz structure welded at a rear end, and a branch pipe welded at the rear end. In the related manufacturing process, a technical solution of air intake at the rear end and air extraction at the front end is adopted, when extracting air to achieve vacuum in the furnace tube, a breather pipe is inserted into the furnace tube from the branch pipe at the rear end to the front end for vacuuming the furnace tube, while other branch pipes are closed. The front end of the furnace tube and the flange on a furnace body are radially sealed. However, there is a gap between the furnace tube flange at the front end of the furnace tube and a furnace body flange, during the vacuuming step, there is a pressure difference between the inside of the furnace tube and the outside of the rear end of the furnace body, the furnace tube will move toward a furnace door (i.e., the left end of FIG. 1) under the action of the pressure difference, which may easily cause the furnace tube to break.

### BRIEF DESCRIPTION OF THE DRAWINGS

FIG. 1 is a schematic structural diagram of a furnace of in the related art.

FIG. 2 is a schematic structural diagram of a furnace tube structure of at least one embodiment of the present disclosure.

FIG. 3 is a cross-sectional view of the furnace tube structure of at least one embodiment of the present disclosure.

FIG. 4 is an enlarged view of a partial structure of the furnace tube structure of at least one embodiment of the present disclosure.

FIG. 5 is a schematic structural diagram of a furnace rear sealing device in the related art.

FIG. 6 is a schematic structural diagram of the furnace rear sealing device in another direction according to at least one embodiment of the present disclosure.

FIG. 7 is a cross-sectional view along the A-A line shown in FIG. 6.

FIG. 8 is a partial enlarged view of the structure shown in FIG. 7.

FIG. 9 is a schematic structural diagram of a rear cover of at least one embodiment of the present disclosure.

FIG. 10 is a schematic diagram of an internal structure of the rear cover of at least one embodiment of the present disclosure.

FIG. 11 is a schematic structural diagram of the rear cover in another direction according to at least one embodiment of the present disclosure.

FIG. 12 is a cross-sectional view along the A-A line shown in FIG. 11.

FIG. 13 is a partial enlarged view of the rear cover of at least one embodiment of the present disclosure.

FIG. 14 is a cross-sectional view along the B-B line shown in FIG. 13.

FIG. 15 is a schematic structural diagram of the structure of FIG. 13 in another direction.

FIG. 16 is a schematic structural diagram of a rear cover of another embodiment of the present disclosure.

FIG. 17 is a structural schematic diagram of an internal structure of the rear cover of another embodiment of the present disclosure.

### DETAILED DESCRIPTION

In order to make the purpose, technical solutions and advantages of the embodiments of the present disclosure clearer, the technical solutions in the embodiments of the present disclosure will be described clearly and completely in conjunction with the drawings in the embodiments of the present disclosure. Based on the embodiments of the present disclosure, all other embodiments obtained by those of ordinary skill in the art without creative work shall fall within the scope of protection of the present disclosure.

Those skilled in the art should understand that, in the disclosure of the present disclosure, “at least one” refers to one or more, and multiple refers to two or more. Unless otherwise defined, all technical and scientific terms used herein have the same meaning as commonly understood by those skilled in the technical field in the present disclosure. The terminology used in the specification of present disclosure is only for the purpose of describing specific embodiments, and is not intended to limit the present disclosure.

It can be understood that, unless otherwise specified in the present disclosure, “/” means “or”. For example, A/B can mean A or B. “A and/or B” in the present disclosure is only an associative relationship describing the associated objects, which means that there can be three relationships: only A, only B, and A and B.

It can be understood that, in the disclosure of the present disclosure, the words such as “first” and “second” are only used for the purpose of distinguishing description, and cannot be understood as indicating or implying relative importance, nor as indicating or implying any order. The features defined with “first” and “second” may explicitly or implicitly include one or more of the features. In the description of the embodiments of the present disclosure, the words such as “exemplary” or “for example” are used as examples, illustrations, or indications. Any embodiment or design solution described as “exemplary” or “for example” in the embodiments of the present disclosure should not be construed as being more preferable or advantageous than other embodiments or design solutions. To be precise, the words such as “exemplary” or “for example” are used to present related concepts in a specific manner.

Those skilled in the art should understand that, in the disclosure of the present disclosure, the terms “longitudinal”, “lateral”, “upper”, “lower”, “front”, “rear”, “left”, “right”, the orientation or positional relationship indicated by “vertical”, “horizontal”, “top”, “bottom”, “inner”, “outer”, etc. are based on the orientation or positional relationship shown in the drawings, which is only for the convenience of describing the present disclosure and to simplify the description, rather than indicating or implying that the device or element referred to must have a specific orientation, or be constructed and operated in a specific orientation, so the above terms should not be understood as limiting the present disclosure.

A semiconductor manufacturing equipment is normally provided for the processing and manufacturing process of photovoltaic cells. A furnace tube structure is provided according to an embodiment of the present disclosure as shown in FIGS. 2 to 5.

The furnace tube structure may be applied in a furnace, which can be a diffusion furnace or other types of furnaces used in a processing and manufacturing process of photovoltaic cells, such as a sintering furnace, a low-temperature furnace, a LPCVD reacting furnace, a PECVD reacting furnace, an oxidation furnace, a boron diffusion furnace, etc., which will not be limited here.

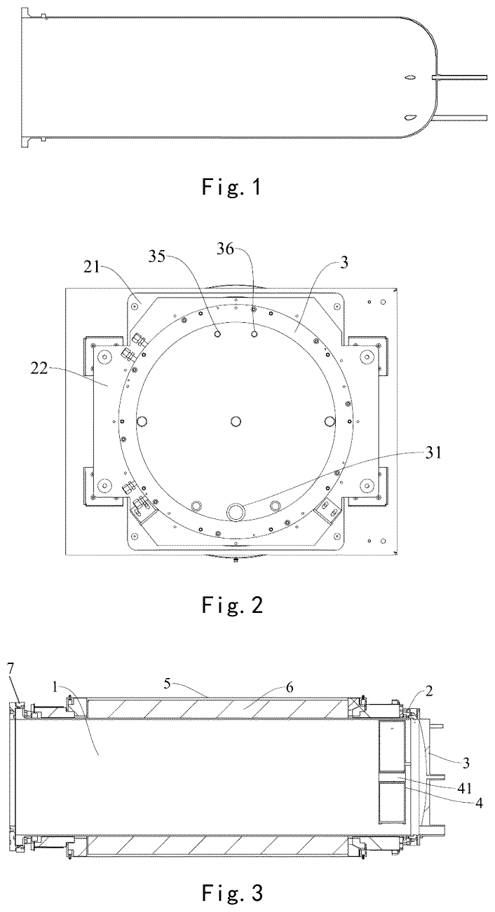

The furnace tube structure provided by the present disclosure, as shown in FIGS. 2 to 4, includes a furnace tube 1 with two ends open, a rear end of the furnace tube 1 is provided with a barrier structure to block the outside environment. The barrier structure includes a flange connection assembly 2 and a rear cover 3. The flange connection assembly 2 is arranged on the rear end of the furnace tube 1, and the flange connection assembly 2 is configured to connect with a furnace body 5. The rear cover 3 is connected to the flange connection assembly 2 and can seal the rear end of the furnace tube 1. In the embodiment, the furnace tube 1 is set up with both ends open, a front end of the furnace tube 1 can be radially secured and sealed to the furnace body 5 through a furnace tube flange 7, the rear end of the furnace tube 1 can be secured and sealed to the to the furnace body 5 through the flange connection assembly 2 and the rear cover 3, the rear end of the furnace tube 1 is provided with the barrier structure to block the outside environment, during a vacuuming step of the furnace tube 1. Since the both ends of the furnace tube 1 is arranged on the furnace body 5, and the furnace tube 1 is set up with both ends open, there is no pressure difference between the two ends of the furnace tube 1, thus the furnace tube 1 may stably remained inside the furnace body 5 without movements. If the furnace tube 1 is fixedly connected with a rear structure and is sealed by the rear structure as shown in FIG. 1, the furnace tube 1 would move towards the front end of the furnace tube 1, caused by pressure difference of the two ends of the furnace tube 1 during a vacuuming step. Reducing the relative movement of the furnace tube 1 and the furnace body 5 reduces the risk of breakage of the furnace tube 1.

In addition, a welding process of the furnace tube of prior art is difficult, the furnace tube is transparent, the front end is welded to the furnace tube flange, and the rear end is welded to a semicircular structure, resulting in a complex manufacturing process and a low rate of manufacturing yield. In the embodiment of the disclosure, the two ends of the furnace tube 1 are open and it is only necessary to weld the furnace tube flange at one end, to improve the manufacturing process and the manufacturing yield. As both ends of the furnace tube 1 are open, and the rear cover 3 seals the rear end of the furnace tube 1. The flange connection assembly 2 and the rear cover 3 realize the contact between the rear end of the furnace tube 1 and the outside, simplifying the entire furnace tube structure, facilitating assembly, and improving manufacturing efficiency.

In the embodiment, the furnace tube 1 can be made of quartz or other materials, and the material of the furnace tube 1 is not specifically limited here.

In some embodiments, the rear cover 3 is provided with a branch tube 31.

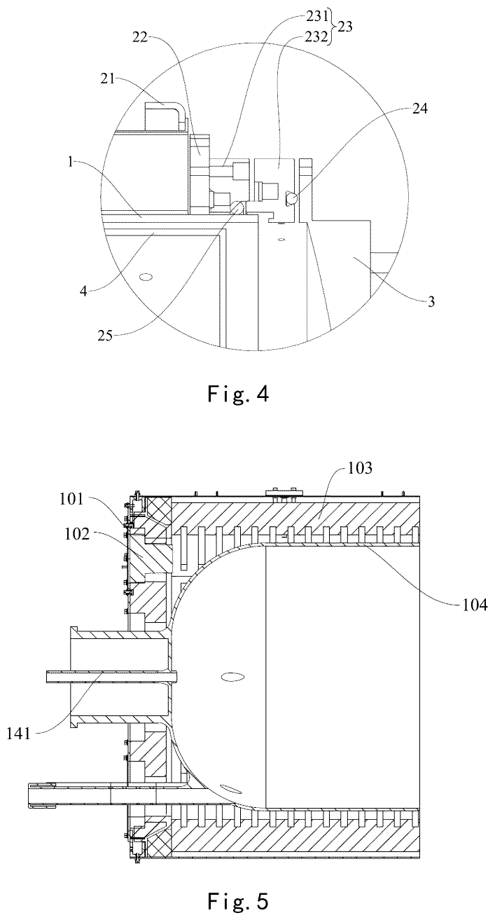

In some embodiments, as shown in FIG. 4, the flange connection assembly 2 includes a fixing plate 21, a flange mounting plate 22, a flange group 23, and a first seal 24. The fixing plate 21 is sleeved on the furnace tube 1. The flange mounting plate 22 is connected to the fixing plate 21, The flange group 23 is connected to the flange mounting plate 22 and the rear cover 3. The first seal 24 is sandwiched between the flange group 23 and rear cover 3. It can be understood that the fixing plate 21, the flange mounting plate 22, and the flange group 23 can ensure that the rear cover 3 is stably connected to the rear end of the furnace tube 1, thereby stably sealing the rear end of the furnace tube 1. The first seal 24 can stably ensure a sealed connection between the flange group 23 and the rear cover 3.

In some specifically embodiments, as shown in FIG. 4, the flange group 23 includes an inner flange 231 and an outer flange 232. The inner flange 231 is mounted on the flange mounting plate 22, the outer flange 232 is connected to the inner flange 231 and the rear cover 3. The first seal 24 is sandwiched between the outer flange 232 and the rear cover 3, and a second seal 25 is provided between the inner flange 231 and the outer flange 232. The inner flange 231 and the outer flange 232 is configured to ensure a sealed connection between the entire flange connection assembly 2 and the rear cover 3, and improve the connection stability thereof. The second seal 25 can ensure the sealing of the connection between the inner flange 231 and outer flange 232.

In some embodiments, both the inner flange 231 and the outer flange 232 are provided with cooling flow channels, a liquid inlet pipeline, and a liquid outlet pipeline, the liquid inlet pipeline and the liquid outlet pipeline are connected with the cooling flow channels. It should be noted that the atmosphere temperature during boron diffusion process exceeds 1000° C. After the end of a first round of the boron diffusion process, the atmosphere temperature of the furnace tube is still above 800° C., so heat will be extracted from the branch pipe 31 along with the air in a vacuuming step of the second round of the boron diffusion process. During the vacuuming step, the temperature of both the inner flange 231 and the outer flange 232 will be rise, if the temperature of the inner flange 231 and outer flange 232 is higher than a threshold, the first seal 24 and the second seal 25 are susceptible to burnout. In the embodiment, both the inner flange 231 and the outer flange 232 are provided with the cooling flow channels, the liquid inlet pipeline, and the liquid outlet pipeline, the liquid inlet pipeline and liquid outlet pipeline are connected with the cooling flow channels. During the vacuuming step, coolant flows in the inner flange 231 and the outer flange 232, which can cool down the inner flange 231 and the outer flange 232, thereby preventing the first seal 24 or the second seal 25 from damaging by the overheated inner flange 231 and the outer flange 232.

Optionally, there is a cooling source connected between the liquid inlet pipeline and the liquid outlet pipeline. Specifically, the liquid outlet pipeline of the cooling source is connected to a pump, the pump is connected to a flow meter and a thermometer, and then connected to the liquid inlet pipeline, the liquid outlet pipeline is connected to a return port of the cooling source. In this way, the coolant for cooling the inner flange 231 and the outer flange 232 circulates, improving the cooling effect of the coolant on the inner flange 231 and the outer flange 232.

In some embodiments, as shown in FIG. 3, the furnace tube structure further includes a heat insulator 4, which is located inside the furnace tube 1 and located at one end of the furnace tube 1 near the rear cover 3, that is, the heat insulator 4 is located at the rear end of the furnace tube 1 and faces the rear cover 3. If the inner flange 231 and the outer flange 232 are heated by the air in the furnace tube 1, the first seal 24, the second seal 25, and a sealing structure mounted on the branch pipe 31 of the rear cover 3 are susceptible to burnout. The heat insulator 4 is configured to provide better heat insulation and prevent the furnace tube 1 from transferring heat to the inner flange 231, the outer flange 232, and the rear cover 3. The temperatures of the inner flange 231, the outer flange 232, and the rear cover 3 are controlled to reduce the risk of burnout of the first seal 24, the second seal 25, and the sealing structure mounted on the branch pipe 31 of the rear cover 3, and the service life of the first seal 24, the second seal 25, and the sealing structure mounted on the branch pipe 31 of the rear cover 3 is extended.

Optionally, in order to facilitate the insertion of an air inlet pipeline inserted into the branch pipe 31 of the rear cover 3 into an interior of the furnace tube 1, the heat insulator 4 is provided with a passing hole 41. An avoidance notch is set on a lower portion of the heat insulator 4 for inserting a vacuuming tube into the furnace tube 1.

In another related art, a rear cover seal for sealing the rear end of the furnace tube 104 can be composed of a rear cover metal plate, an aluminum silicate insulation layer and some other components. As shown in FIG. 5, the aluminum silicate heat insulation layer 102 is mounted on the rear cover metal plate 101 to form the rear cover seal, the rear cover seal is fixedly connected to a thermal field 103 of the furnace tube 104 through bolts, so that the furnace tube 1 is isolated and protected. Since a furnace tube 104 and the rear cover seal are mounted on the thermal field 103 as a unibody, and there are multiple branch pipes 141 at the rear end of the furnace tube 104, the structural processing of the related art is difficult, and there are certain requirements of assembly techniques during mounting, which are difficult, the quartz tube may be damaged during the mounting, and the production efficiency is low.

One embodiment of the present disclosure provides a furnace rear sealing device. The furnace rear sealing device has lower requirements for assembly techniques and is easier for mounting, which facilitates the assemble process and disassemble process of the furnace rear sealing device.

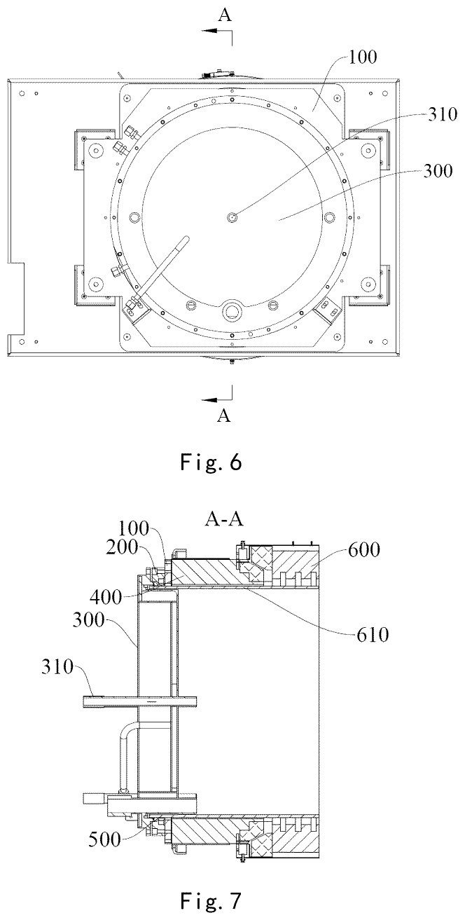

Referring to FIGS. 6 to 8, a specific structure of the furnace rear sealing device according to an embodiment of the present disclosure is described.

The furnace rear sealing device is mounted to a rear end of a furnace body 600. As shown in FIGS. 6 to 8, the furnace rear sealing device includes a flange mounting plate 100, a furnace rear flange 200, and a rear cover 300. The flange mounting plate 100 is arranged on the rear end of the furnace body 600. The furnace rear flange 200 is mounted on the flange mounting plate 100. The rear cover 300 is connected to the furnace rear flange 200 for sealing the rear end of the furnace body 600. The rear cover 300 is provided with an air pipe 310 that communicates with a furnace tube 610 in the furnace body 600. A process for assembling the furnace rear sealing device include: mounting the flange mounting plate 100 on the rear end of the furnace body 600, then mounting the furnace rear flange 200 to the flange mounting plate 100, and finally mounting the rear cover 300 on the flange mounting plate 100. Since the rear cover 300 is provided with the air pipe 310 that communicates with the furnace tube 610, the branch pipe 41 does not have to pass through the rear cover seal as shown in FIG. 5, which facilitates the assemble process and disassemble process of the furnace rear sealing device.

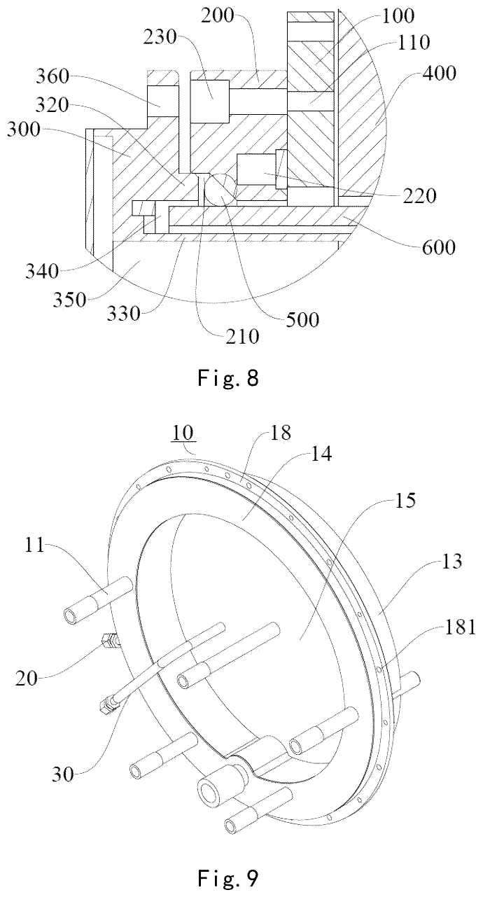

In some embodiments, as shown in FIGS. 7 and 8, the furnace rear sealing device further includes a heat insulator 400. The heat insulator 400 is sandwiched between the flange mounting plate 100 and an end surface of the furnace body 600. It can be understood that the heat insulator 400 is configured to restrict the heat transfer from the furnace body 600 to the flange mounting plate 100, thereby reducing the temperature rise of the furnace rear sealing device. In the embodiment of the present disclosure, materials of the heat insulator 400 can be selected according to actual needs, and the specific material of the heat insulator 400 is not limited here.

In some embodiments, as shown in FIG. 8, a third seal 500 is sandwiched between the furnace rear flange 200 and the rear cover 300. The third seal 500 sandwiched between the furnace rear flange 200 and the rear cover 300 can ensure the sealing of the connection between the furnace rear flange 200 and the rear cover 300, and ensuring the sealing of the furnace rear sealing device to the rear end of the furnace body 600. The rear end of the furnace body 600 is sealed by the third seal 500 which is compressed between the furnace rear flange 200 and the rear cover 300. The area where arranged the third seal 500 forms the only sealing area, which reduces a check difficulty of air leakage. In the embodiment of the present disclosure, a specific material and model of the third seal 500 can be selected according to actual needs, which are not limited here.

In some embodiments, as shown in FIG. 8, a mating groove 210 is defined on one side of the furnace rear flange 200 facing the rear cover 300. The rear cover 300 is provided with a mating protrusion 320 on one side facing the furnace rear flange 200. At least a portion of the third seal 500 is accommodated in the mating groove 210, and the third seal 500 can be compressed by the surface of the mating protrusion 320 and the inner surface of the mating groove 210. The matching groove 210 is configured to restrict the position of the third seal 500 on the furnace rear flange 200. It can be understood that through the connection of the mating protrusion 320 and the mating groove 210, on the one hand, the connection stability of the furnace rear flange 200 and the rear cover 300 can be improved, on the other hand, the third seal 500 can be mounted in the mating groove 210 and pressed by the matching protrusions 320, which can improve the sealing of the connection of the furnace rear flange 200 and the rear cover 300, thereby further improving the sealing of the entire furnace rear sealing device to the rear end of the furnace body 600.

In some embodiments, as shown in FIG. 8, the rear cover 300 is provided with an inserting protrusion 330, the inserting protrusion 330 is inserted into the furnace tube 610, and the air pipe 310 (see FIG. 7) is inserted into furnace tube 610 through the inserting protrusion 330. The mounting of the rear cover 300 is facilitated by inserting the inserting protrusion 330 into the furnace tube 610. Simply aligning the inserting protrusion 330 with the rear end of the furnace tube 610 and then pushing the inserting protrusion 330 into the furnace tube 610, the relative position of the inserting protrusion 330 and the furnace tube 610 is limited. And then, the furnace rear flange 200 and the rear cover 300 can be easily mounted on the flange mounting plate 100 which has already connected to the furnace tube 610. The inserting protrusion 330 provided on the air pipe 310 can ensure the communication between the air pipe 310 and the furnace pipe 610, thereby facilitating the air intake or exhaust of the furnace pipe 610.

In some embodiments, as shown in FIG. 8, the rear cover 300 is further provided with an inserting groove 340 surrounding the inserting protrusion 330, and one end of the furnace tube 610 is inserted into the inserting groove 340. Inserting one end of the furnace tube 610 into the inserting groove 340 improves the sealed connection of the furnace tube 610 and the rear cover 300, thereby avoiding air leakage in the furnace during actual operation.

In some embodiments, as shown in FIG. 8, a first cooling channel 220 is defined on one side of the furnace rear flange 200 facing the flange mounting plate 100. The first cooling channel 220 is filled with coolant, and the coolant can flow in the first cooling channel 220. It can be understood that the third seal 500 is sandwiched between the furnace rear flange 200 and the rear cover 300 for improving the sealed connection between the furnace rear flange 200 and the rear cover 300. If the temperature of the furnace rear flange 200 is too high, the service life of the third seal 500 will be reduced, and a new third seal 500 will soon be replaced. The coolant flowed in the first cooling channel 220 can reduce the temperature rise of the furnace rear flange 200, thereby avoiding that reducing the service life of the third seal 500 due to the temperature of the furnace rear flange 200 is too high, extending the replacement cycle of the third seal 500, and conducive to increasing production capacity.

In some embodiments, as shown in FIG. 8, the rear cover 300 is provided with a second cooling channel 350, a liquid inlet pipeline, and a liquid outlet pipeline, the liquid inlet pipeline and the liquid outlet pipeline are communicated with the second cooling channel 350. If the temperature of the rear cover 300 is too high, the service life of the third seal 500 will be reduced, in the actual working process, the third seal 500 needs to be replaced frequently, thereby affecting normal production. In the embodiment, the rear cover 300 is provided with the second cooling channel 350, the rear cover 300 can be cooled by the coolant flowed in the second cooling channel, the third seal 500 is also can be cooled, reducing the frequency of replacement of the third seal 500, and conducive to increasing production capacity.

In some embodiments, as shown in FIG. 8, the rear cover 300 is provided with a first mounting hole 360, the furnace rear flange 200 is provided with a second mounting hole 230 corresponding to the first mounting hole 360, the flange mounting plate 100 is provided with a third mounting hole 110 corresponding to the second mounting hole 230. A connecting piece may insert through the first mounting hole 360, the second mounting hole 230, and the third mounting hole 110 to securely connect the rear cover 300, the furnace rear flange 200, and the flange mounting plate 100. The securely connection among the rear cover 300, the furnace rear flange 200, and the flange mounting plate 100 by the insertion of the connecting piece through the first mounting hole 360, the second mounting hole 230, and the third mounting hole 110, which can facilitate the assemble and disassemble of the furnace rear sealing device.

### Embodiment

As shown in FIGS. 6 to 8, the furnace rear sealing device provided by the present disclosure includes the flange mounting plate 100, the furnace rear flange 200, the rear cover 300, the heat insulator 400, and the third seal 500. The flange mounting plate 100 is set on the rear end of the furnace body 600, the rear cover 300 is provided with the first mounting hole 360, the furnace rear flange 200 is provided with the second mounting hole 230 corresponding to the first mounting hole 360, the flange mounting plate 100 is provided with the third mounting hole 110 corresponding to the second mounting hole 230, the connecting piece is inserted through the first mounting hole 360, the second mounting hole 230, and the third mounting hole 110 to securely connect the rear cover 300, the furnace rear flange 200, and the flange mounting plate 100. The rear cover 300 is provided with the air pipe 310 communicating with the furnace tube 610 in the furnace body 600. The heat insulator 400 is sandwiched between the flange mounting plate 100 and an end surface of the furnace body 600. The furnace rear flange 200 is provided with the mating groove 210 on one side facing the rear cover 300, and the rear cover 300 is provided with the mating protrusion 320 on one side facing the furnace rear flange 200, the mating protrusion 320 is used to press the third seal 500 to be secured to the mating groove 210. The rear cover 300 is provided with the inserting protrusion 330, the air pipe 310 is inserted into the inserting protrusion 330, and the inserting protrusion 330 is inserted into the furnace tube 610. A side of the furnace rear flange 200 facing the flange mounting plate 100 is provided with the first cooling channel 220, coolant flows in the first cooling channel 220. The rear cover 300 is provided with a second cooling channel 350, a liquid inlet pipeline, and a liquid outlet pipeline, the liquid inlet pipeline and the liquid outlet pipeline are communicated with the second cooling channel 350.

The present disclosure further provides a furnace, including the furnace rear sealing device, the furnace body 600, and the furnace tube 610. The furnace tube 610 is mounted in the furnace body 600, the furnace rear sealing device is configured to seal the rear end of the furnace body 600 and seal the rear end of the furnace tube 610.

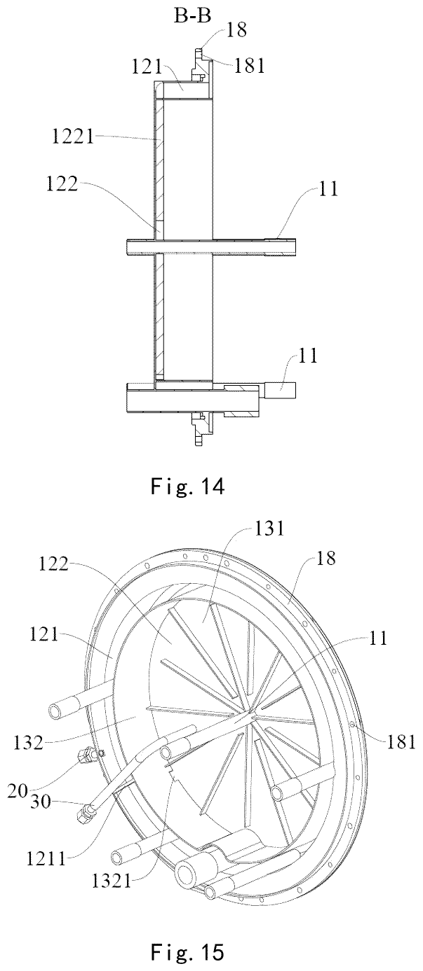

As shown in FIGS. 9 to 15, a specific structure of a rear cover 10 according to an embodiment of the present disclosure is described.

The rear cover 10 provided by the present disclosure is used to seal the rear end of the furnace. The rear cover 10 is provided with at least one air pipe 11 communicated with the inside of the furnace tube 610 (shown in FIGS. 7 and 8). A cooling cavity 12 is defined in the rear cover 10, and filled with coolant. Since the rear cover 10 is provided with the air pipe 11 that communicates with the furnace tube 610 inside the furnace body, the step that pass through the branch pipe on the furnace tube 610 during mounting the rear cover 10 can be omitted. The requirements for mounting the rear cover 10 are lower, and the mounting of the rear cover 10 is easier for mounting, which facilitates the assemble process and disassemble process of the rear cover 10. Coolant flowing in the cooling cavity 12 can reduce the heat radiated from the inside of the furnace tube 610 to the rear end of the furnace body 600, thereby reducing the temperature rise of the rear end of the furnace tube 610 and protecting workers close to the furnace. The temperature of the third seal 500 mounted at the rear end of the furnace tube 610 can be kept below a threshold, reducing the rate of aging of the third seal 500 and extending the service life of the third seal 500.

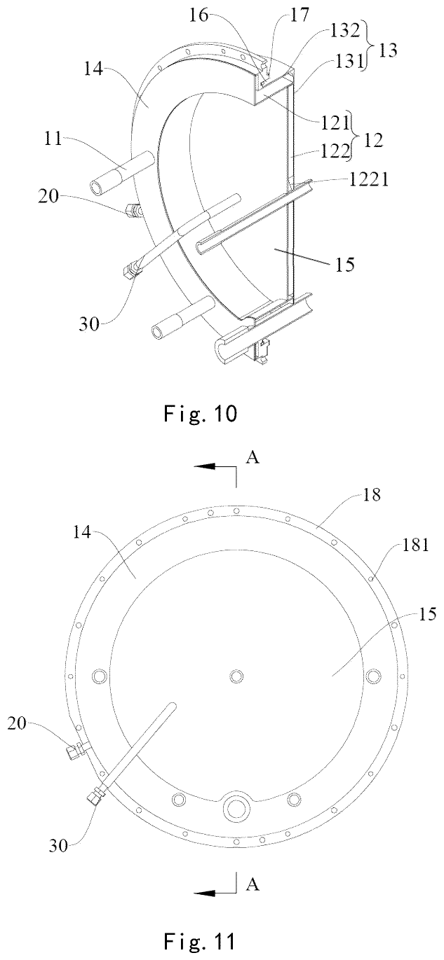

In some embodiments, as shown in FIGS. 10 and 11, the cooling cavity 12 includes a first cavity 121 and a second cavity 122 communicating with the first cavity 121. A longitudinal section of the second cavity 122 is perpendicular to an axial direction of the furnace tube 610, the first cavity 121 is arranged surrounding a circumference of the second cavity 122. It can be understood that since the first cavity 121 is an annular cooling channel, coolant in the first cavity can better cool an inner ring of the third seal 500, thereby the temperature of the third seal 500 mounted at the rear end of the furnace tube 610 can be kept below the threshold. In some embodiments, the second cooling channel 350 shown in FIG. 8 may be set in a same way as the first cavity 121 shown in FIGS. 10 and 11, the second cooling channel 350 shown in FIG. 8 is an annular cooling runner for cooling down the third seal 500. The longitudinal section of the second cavity 122 is perpendicular to the axial direction of the furnace tube 610, so that the second cavity 122 can reduce the heat radiated from the inside of the furnace tube 610 to the rear end of the furnace body, thereby further cooling the third seal 500.

In some specific embodiments, as shown in FIG. 13, a plurality of water baffles 1221 is defined in the second cavity 122, and spaced along the circumferential direction of the furnace tube 610. The plurality of water baffles 1221 can divide the second cavity 122 into a plurality of water channels communicated together for flowing of coolant that covers the entire second cavity 122, and coolant flows within the plurality of water channels to extend a flow path of coolant, so that improve the cooling effect of coolant.

In some specific embodiments, as shown in FIG. 13, the air pipe 11 passes through the second cavity 122, in the two adjacent water baffles 1221 along the circumferential direction of the furnace tube 610, one end of one of the two adjacent water baffles 1221 is connected to the air pipe 11, and the other end is spaced apart from a side wall of the second cavity 122; one end of the other one of the two adjacent water baffles 1221 is connected to the side wall of the second cavity 122, the other end is spaced apart from the air pipe 11. It can be understood that during a coolant circulation process, the end of the water baffle 1221 and the inner wall of the second cavity 122 are spaced apart to form a flow opening for flowing of the coolant, and the end of the water baffle 1221 spaced apart from the air pipe 11 can also form another flow opening for flowing the coolant. The plurality of water channels formed by every two adjacent water baffles 1221 are spaced along the radial direction of the second cavity 122, which can extend the flow path of coolant, thereby improves the cooling effect of the coolant.

In the embodiment of the present disclosure, the specific shape of each of the water baffles 1221 can be a straight plate or a curved plate according to actual needs, or it can also be a plate structure of other shapes, the specific structure of the water baffle 1221 is not limited.

In some specific embodiments, as shown in FIG. 15, the first cavity 121 is also provided with a baffle 1211, and the baffle 1211 is located between a liquid inlet port and a liquid outlet port of the first cavity 121. It can be understood that since the baffle 1211 is located between the liquid inlet port and the liquid outlet port of the first cavity 121. In the circumferential direction of the first cavity 121, the baffle 1211 is located between a communication hole 1321 of the first cavity 121 and the second cavity 122 and the liquid inlet pipeline of the first cavity 121. In the actual working process, since the first cavity 121 is provided with the baffle 1211, after the coolant enters the first cavity 121 from the liquid inlet port of the first cavity 121, the coolant needs to flow a longer path to enter the second cavity 122 through the communication hole 1321. Thus, in the actual cooling process, the coolant can sequentially cool the first cavity 121 and the second cavity 122, so as to preferentially protect the third seal 500.

In some embodiments, as shown in FIGS. 10, 11, and 13, the rear cover 10 is provided with a liquid inlet pipeline 20 and a liquid outlet pipeline 30. The liquid inlet pipeline 20 is communicated with the first cavity 121, the liquid inlet pipeline 30 is communicated with the second cavity 122. In the actual working process, the coolant from an external liquid source enters the first cavity 121 through the liquid inlet pipeline 20, the coolant fills the first cavity 121 and then enters the second cavity 122, and then returns to the external liquid source through the liquid outlet pipeline 30. In this way, the coolant keeps circling in the entire cooling cavity 12 during actual working process, which is beneficial to cooling the third seal 500 and the rear end of the furnace body.

In some embodiments, as shown in FIGS. 10 and 15, the rear cover 10 includes an enclosure plate 13, an outer sealing plate 14, and an inner sealing plate 15. The enclosure plate 13 includes a vertical plate 131 and two annular plates 132 connected to the vertical plate 131. The two annular plates 132 are arranged at intervals. The outer sealing plate 14 is connected to the two annular plates 132, the outer sealing plate 14 and the two annular plates 132 cooperatively define the first cavity 121. The inner sealing plate 15 is connected to an inner peripheral wall of the annular plate 132 located interiorly, the inner sealing plate 15 and the vertical plate 131 cooperatively defines the second cavity 122. The annular plate 132 located interiorly is provided with the communication hole 1321 that communicates the first cavity 121 and the second cavity 122. In the actual assemble process, the outer sealing plate 14 and the inner sealing plate 15 are connected to the enclosure plate 13 through sealing connection such as welding. The structure of the rear cover 10 can be split into multiple plate-shaped structures, which can facilitate the manufacture of the rear cover 10 and improve manufacturing efficiency and manufacturing yield of the rear cover 10.

Preferably, the communication hole 1321 is symmetrically arranged with the liquid inlet pipeline of the first cavity 121, that is the baffle 1211 is arranged between the communication hole 1321 and the liquid inlet pipeline of the first cavity 121, so that the coolant can be filled in the first cavity 121 before entering the second cavity 122 through the communication hole 1321, ensuring that a content of the coolant in the first cavity 121.

In some embodiments, as shown in FIGS. 7 and 10, a side of the rear cover 10 facing the furnace tube 610 is provided with an engage slot 16 for engaging with the furnace tube 610. One end of the furnace tube 610 is inserted into the engage slot 16 to ensure the sealing of the furnace tube 610 by the rear cover 10, thereby avoiding air leakage in the furnace during actual operation.

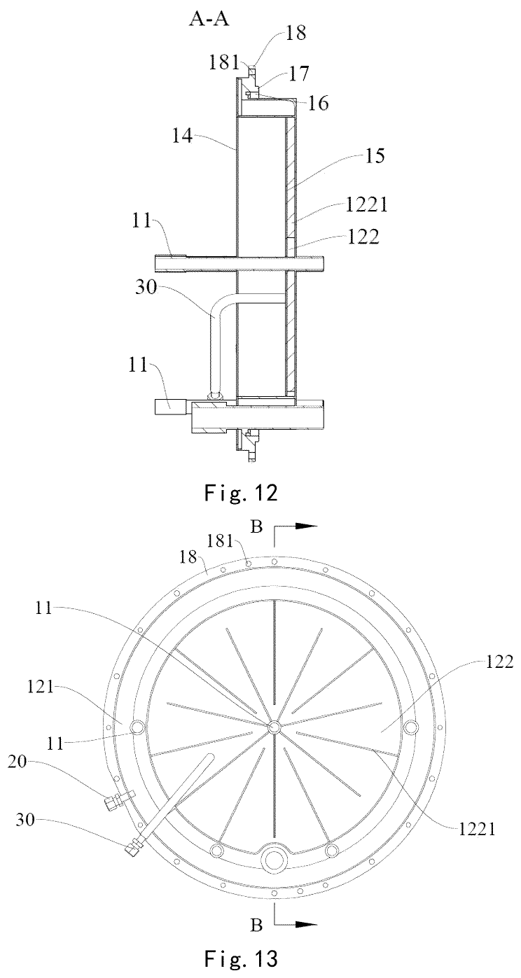

In some embodiments, as shown in FIGS. 7 and 12, the side of the rear cover 10 facing the furnace tube 610 is provided with a sealing protrusion 17 for resisting against the third seal 500. In the actual assemble process, after the rear cover 10 is connected to the furnace rear flange 200, the sealing protrusion 17 can press the third seal 500, thereby further improving the sealing of the rear cover 10 to the rear end of the furnace that is opened.

In some embodiments, as shown in FIG. 9, the rear cover 10 is provided with a flange plate 18 along the circumferential direction of the rear cover 10, and the flange 18 is used to connect with the furnace rear flange 200. Through the connection of the flange plate 18 and the furnace rear flange 200, on one hand, the connection stability of the rear cover 10 and the furnace rear flange 200 is improved; on the other hand, the sealing of the connection of the rear cover 10 and the furnace rear flange 200 is ensured.

### Embodiment

The specific structure of the rear cover 10 of a specific embodiment of the present disclosure is described below with reference to FIGS. 7 to 15.

As shown in FIGS. 7 to 15, the rear cover 10 is provided with the plurality of air pipes 11, the liquid inlet pipeline 20, and the liquid inlet pipeline 30. The rear cover 10 includes the enclosure plate 13, the outer sealing plate 14, and the inner sealing plate 15. The enclosure plate 13 includes the vertical plate 131 and the two annular plates 132 connected to the vertical plate 131. The two annular plates 132 are arranged at intervals. The outer sealing plate 14 is connected to the two annular plates 132, the outer sealing plate 14 and the two annular plates 132 cooperatively define the first cavity 121. The inner sealing plate 15 is connected to an inner peripheral wall of the annular plate 132 located interiorly, the inner sealing plate 15 and the vertical plate 131 cooperatively defines the second cavity 122. The liquid inlet pipeline 20 is communicated with the first cavity 121, the liquid inlet pipeline 30 is communicated with the second cavity 122. The second cavity 122 is provided with the plurality of water baffles 1221 spaced along the circumferential direction of the furnace tube 610. One of the plurality of air pipes 11 passes through the second cavity 122, in the two adjacent water baffles 1221 along the circumferential direction of the furnace tube 610, one end of one of the water baffles 1221 is connected to the air pipe 11, and the other end is spaced apart from a side wall of the second cavity 122; one end of the other one of the water baffles 1221 is connected to the side wall of the second cavity 122, the other end is spaced apart from the air pipe 11. A side of the rear cover 10 facing the furnace tube 610 is provided with the engage slot 16 for engaging with the furnace tube 610, the sealing protrusion 17 for resisting against the third seal 500, and the flange plate 18 for connecting with the furnace rear flange 200. The first cavity 121 is also provided with the baffle 1211, in the circumferential direction of the first cavity 121, the baffle 1211 is located between a communication hole 1321 of the first cavity 121 and the second cavity 122 and the liquid inlet pipeline of the first cavity 121.

The rear cover 10 of the embodiment includes at least advantages as follows:

First: since the rear cover 10 is provided with the at least one air pipe 11 that communicates with the furnace tube 610 in the furnace body, there is no need to mount a branch pipe that passes through the furnace tube 610 during the mounting process of the rear cover 10 as in the related art, which facilitates the assembly and disassembly of the rear cover 10.

Second: since the rear cover 10 includes the first cavity 121 and the second cavity 122 for circulating the coolant, the coolant in the first cavity 121 can better realize the cooling of the inner ring of the third seal 500, the second cavity 122 can reduce the heat radiated from the inside of the furnace tube 610 to the rear end of the furnace body, thereby further cooling the third seal 500 at the rear end of the furnace body.

Third: the water baffles 1221 in the second cavity 122 can divide the second cavity 122 into water channels for flowing of the coolant that covers the entire second cavity 122, which is beneficial for the coolant in the second cavity 122 to reduce the heat radiated from the inside of the furnace tube 610 to the rear end of the furnace body.

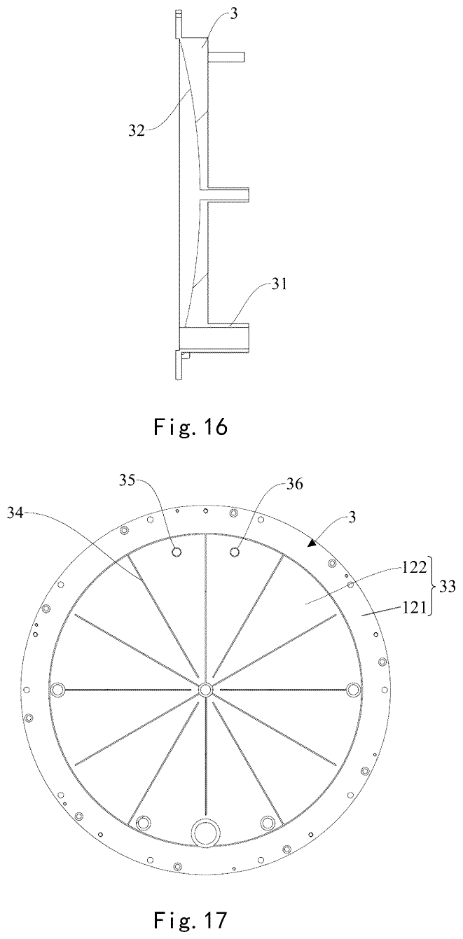

In one embodiment, as shown in FIG. 16, an inner wall of the rear cover 3 facing the rear end (which is opened) of the furnace tube 1 is an arc surface 32, and the arc surface 32 is protruding in a direction away from the furnace tube 1. During the vacuuming step, there will be a pressure difference between the inner and outer sides of the rear cover 3, compared with a flat surface, an anti-deformation ability of the arcuate surface 32 is better. The inner wall of the rear cover 3 facing the rear end of the furnace tube 1 is the arcuate surface 32, and the arc surface 32 protruding away from the furnace tube 1 can ensure the anti-deformation ability of the rear cover 3, thereby avoiding air leakage caused by excessive deformation of the rear cover 3 during the vacuuming step.

Preferably, the arcuate surface 32 is provided with an anti-corrosion and anti-high temperature coating layer, which can prevent the material from falling off on the inner wall of the open end of the rear cover 3 facing the furnace tube 1 during the process, and avoid the material to be processed in the furnace body 5 being contaminated.

In one embodiment, a cooling fan may be provided on an outer wall of the rear cover 3 away from the open end of the furnace tube 1. Compared to the previous coolant solution of providing a cooling cavity on the rear cover 3 and connecting the liquid inlet pipeline and the liquid outlet pipeline on the rear cover 3, in the embodiment, the cooling fan is mounted directly on the outer wall of the rear cover 3 away from of the open end of the furnace tube 1, and heat dissipation of the rear cover 3 is achieved by air cooling, which ensures the heat dissipation effect while simplifying the structure of the rear cover 3, the manufacturing cost of the rear cover 3 is reduced, the assembly difficulty of the entire furnace tube structure is reduced, and the assembly efficiency of the furnace tube structure is improved.

In some other specific embodiments, as shown in FIG. 17, the rear cover 3 is provided with a cooling cavity 33, a liquid inlet pipeline 35, and a liquid outlet pipeline 36, the liquid inlet pipeline 35 and the liquid outlet pipeline 36 are communicated with the cooling cavity 33. Compared with the embodiment shown in FIGS. 10 to 16, the liquid inlet pipeline 35 and the liquid outlet pipeline 36 of the embodiment shown in FIG. 17 are arranged in different positions than the liquid inlet pipeline 20 and the liquid outlet pipeline 30 of the embodiment shown in FIGS. 10 to 16. For example, the liquid inlet pipeline 35 and the liquid outlet pipeline 36 of the embodiment shown in FIG. 17 can both be arranged to communicate with the second cavity 122 of the cooling cavity 33. Or in another specific embodiment, the liquid inlet pipeline 35 and the liquid outlet pipeline 36 of the embodiment shown in FIG. 17 can both be arranged to communicate with the first cavity 121 of the cooling cavity 33.

During the actual vacuuming step, referring to FIGS. 9 and 17, the branch pipe 31 of the rear cover 3 is inserted into the furnace tube for vacuuming. After the furnace tube is inserted with the branch pipe 31, there are gaps at both ends of the branch pipe 31. In order to ensure stable vacuuming, a sealing structure is provided between the branch pipe 31 and the furnace tube. In the boron diffusion process, the temperature for the boron diffusion process exceeds 1000° C. After the first round of the boron diffusion process, the atmosphere temperature of the furnace tube is still above 800° C., at this time, heat will be extracted from the branch pipe 31 together with the air in the vacuuming step of the second round of the boron diffusion process, meanwhile, the temperature of the branch pipe 31 will rise rapidly, and the sealing structure of the branch pipe 31 may be burned out. In the embodiment, the rear cover 3 is provided with the cooling cavity 33, the liquid inlet pipeline 35, and the liquid outlet pipeline 36, the liquid inlet pipeline 35 and the liquid outlet pipeline 36 are communicated with the cooling cavity 33. During the actual vacuuming step, coolant flows in the rear cover 3, a part of the branch pipe 31 is immersed in the coolant, the temperature of the branch pipe 31 can be cooled, thereby preventing the overheated branch pipe 31 from damaging the sealing structure, and extending the service life of the sealing structure at the branch pipe 31.

Optionally, a cool source is connected between the liquid inlet pipeline 35 and the liquid outlet pipeline 36. Specifically, a liquid outlet of the cool source is connected to a pump, the pump is connected to a flow meter and a thermometer, and then connected to the liquid inlet pipeline 35. The liquid outlet pipeline 36 is connected to a return port of the cool source. In this way, the coolant in the rear cover 3 is circulated, and the cooling function can be better realized.

In some more specific embodiments, the cooling cavity 33 is provided with a plurality of water baffles 34 spaced apart along the circumferential direction of the rear cover 3. The plurality of water baffles 34 may divide the cooling cavity 33 into labyrinth-like flow channels to prevent the coolant from being in a “dead water” state, ensuring that the coolant flows in the cooling chamber 33, and improving the cooling effect. It should be noted that the shape, size, quantity and arrangement of the water baffles 34 can be selected according to actual needs.

### Embodiment

As shown in FIGS. 2 to 4, 16, and 17, the furnace tube structure of the embodiment includes the furnace tube 1, the flange connection assembly 2, the rear cover 3, and the heat insulator 4. Two ends of the furnace tube 1 are open. The flange connection assembly 2 includes the fixing plate 21, the flange mounting plate 22, the flange group 23, and the first seal 24. The fixing plate 21 is sleeved on the furnace tube 1, the flange mounting plate 22 is connected to the fixing plate 21, the flange group 23 is connected to the flange mounting plate 22 and connected to the rear cover 3, and the first seal 24 is sandwiched between the flange group 23 and rear cover 3. The second seal 25 is also provided between the inner flange 231 and the outer flange 232. The heat insulator 4 is located inside the furnace tube 1, and is located at one end of the furnace tube 1 near the rear cover 3. The rear cover 3 is provided with the cooling cavity 33, the liquid inlet pipeline 35, and the liquid outlet pipeline 36, the liquid inlet pipeline 35 and the liquid outlet pipeline 36 are communicated with the cooling cavity 33. The cooling cavity 33 is provided with the plurality of water baffles 34 spaced apart along the circumferential direction of the rear cover 3. The inner wall of the rear cover 3 facing the rear end (which is opened) of the furnace tube 1 is the arc surface 32, and the arc surface 32 is protruding in a direction away from the furnace tube 1.

The furnace tube structure of the embodiment includes at least advantages as follows:

First: since two ends of the furnace tube 1 are open, the rear cover 3 seals the rear end of the furnace tube 1, during the vacuuming step, the furnace tube 1 may stably remained inside the furnace body 5 without movements, which can prevent the furnace tube 1 from being broke.

Second: two ends of the furnace tube 1 are open, and it is only necessary to weld the furnace tube flange at one end, which the structure is simple, the manufacturing is convenient, and the product yield is high.

Third: the rear cover 3 is provided with the cooling cavity 33, the liquid inlet pipeline 35, and the liquid outlet pipeline 36, the liquid inlet pipeline 35 and the liquid outlet pipeline 36 are communicated with the cooling cavity 33, during the vacuuming step, coolant flows in the rear cover 3, which cools the branch pipe 31, thereby preventing the overheated branch pipe 31 from damaging the sealing structure, and extending the service life of the sealing structure at the branch pipe 31.

Fourth: the inner wall of the rear cover 3 facing the rear end of the furnace tube 1 is the arcuate surface 32, which can ensure the anti-deformation ability of the rear cover 3, thereby avoiding air leakage caused by excessive deformation of the rear cover 3 during the vacuuming step.

The present disclosure further provide a furnace, including the furnace body 5, a heating device 6, and the aforementioned furnace tube structure, the furnace tube structure is arranged in the furnace body 5, and the heating device 6 is located in the furnace body 5 and sleeved on the furnace tube 1.

The furnace of the present disclosure includes the furnace tube structure, the furnace is safer to use and more reliable, and can better prevent the furnace tube from being broken.

Even though numerous characteristics and advantages of the present technology have been set forth in the foregoing description, together with details of the structure and function of the present disclosure, the disclosure is illustrative only, and changes may be made in the detail, especially in matters of shape, size, and arrangement of the parts within the principles of the present disclosure, up to and including the full extent established by the broad general meaning of the terms used in the claims. It will therefore be appreciated that the exemplary embodiments described above may be modified within the scope of the claims.

What is claimed is:

1. A furnace tube structure comprising:
a furnace tube arranged in a furnace body, two ends of the furnace tube being open;
a flange connection assembly arranged on a rear end of the furnace tube, the flange connection assembly connected to the furnace body; and
a rear cover connected to the flange connection assembly, the rear cover sealing a rear end of the furnace body and securing the furnace tube to the furnace body.

2. The furnace tube structure according to claim 1, wherein the flange connection assembly comprises:
a fixing plate sleeved on the furnace tube;
a flange mounting plate connected to the fixing plate;
a flange group connected to the flange mounting plate and the rear cover; and
a first seal sandwiched between the flange group and rear cover for sealing a connection between the flange group and the rear cover.

3. The furnace tube structure according to claim 2, wherein the flange connection assembly further comprises a second seal, the flange group comprises an inner flange and an outer flange, the inner flange is mounted on the flange mounting plate, the outer flange is connected to the inner flange and the rear cover, the first seal is sandwiched between the outer flange and the rear cover, and the second seal is sandwiched between the inner flange and the outer flange.

4. The furnace tube structure according to claim 1, wherein an inner wall of the rear cover facing the rear end of the furnace tube is an arc surface, the arc surface is protruding in a direction away from the furnace tube.

5. The furnace tube structure according to claim 1, further comprising a heat insulator arranged in the furnace tube, wherein the heat insulator is located at the rear end of the furnace tube and faces the rear cover.

6. A furnace rear sealing device configured to seal a rear end of a furnace body, the furnace rear sealing device comprising:
a flange mounting plate arranged on the rear end of the furnace body;
a furnace rear flange mounted on the flange mounting plate; and
a rear cover connected to the furnace rear flange and configured to seal the rear end of the furnace body, the rear cover provided with an air pipe that communicates with a furnace tube in the furnace body.

7. The furnace rear sealing device according to claim 6, wherein the rear cover is provided with an inserting protrusion, the air pipe is inserted into the inserting protrusion, and the inserting protrusion is inserted into the furnace tube; the rear cover is further provided with an inserting groove, the inserting groove is surrounding the inserting protrusion, and the furnace tube is inserted into the inserting groove.

8. The furnace rear sealing device according to claim 6, further comprising a third seal sandwiched between the furnace rear flange and the rear cover, wherein furnace rear flange is provided with a mating groove on one side facing the rear cover, the rear cover is provided with a mating protrusion on one side facing the furnace rear flange, the mating protrusion is configured to press the third seal to be secured to the mating groove.

9. The furnace rear sealing device according to claim 6, wherein a side of the furnace rear flange facing the flange mounting plate is provided with a first cooling channel, the first cooling channel is configured to flow with coolant.

10. The furnace rear sealing device according to claim 6, wherein the rear cover is provided with a second cooling channel, a liquid inlet pipeline, and a liquid outlet pipeline, the liquid inlet pipeline and the liquid outlet pipeline are communicated with the second cooling channel, the second cooling channel is configured to flow with coolant.

11. The furnace rear sealing device according to claim 6, wherein the rear cover is provided with a first mounting hole, the furnace rear flange is provided with a second mounting hole corresponding to the first mounting hole, the flange mounting plate is provided with a third mounting hole corresponding to the second mounting hole; the first mounting hole, the second mounting hole, and the third mounting hole are configured to be inserted through with a connecting piece to securely connect the rear cover, the furnace rear flange, and the flange mounting plate.

12. The furnace rear sealing device according to claim 6, wherein the rear cover is provided with a cooling cavity therein, the cooling cavity is configured to flow with coolant, a part of the cooling cavity is provided in a structure of the rear cover, the structure of the rear cover is configured to seal the rear end of the furnace body.

13. The furnace rear sealing device according to claim 12, wherein the cooling cavity comprises a first cavity and a second cavity communicating with the first cavity, a longitudinal section of the second cavity is perpendicular to an axial direction of the furnace tube, the first cavity is arranged surrounding a circumference of the second cavity.

14. The furnace rear sealing device according to claim 13, wherein the second cavity is provided with a plurality of water baffles spaced along a circumferential direction of the furnace tube; the air pipe passes through the second cavity, in the two adjacent water baffles along the circumferential direction of the furnace tube,

15. The furnace rear sealing device according to claim 14, wherein the air pipe passes through the second cavity, in two adjacent water baffles of the plurality of water baffles along the circumferential direction of the furnace tube, one end of one of the plurality of water baffles is connected to the air pipe, and the other end is spaced apart from a side wall of the second cavity; one end of the other one of the plurality of water baffles is connected to the side wall of the second cavity, the other end is spaced apart from the air pipe.

16. The furnace rear sealing device according to claim 13, wherein the first cavity is also provided with a baffle, the baffle is located between a liquid inlet port and a liquid outlet port of the first cavity.

17. The furnace rear sealing device according to claim 13, wherein the rear cover is provided with a liquid inlet pipeline and a liquid inlet pipeline, the liquid inlet pipeline is communicated with the first cavity, the liquid inlet pipeline is communicated with the second cavity.

18. The furnace rear sealing device according to claim 13, wherein the rear cover comprises:
an enclosure plate comprising a vertical plate and two annular plates connected to the vertical plate, the two annular plates are arranged at intervals;
an outer sealing plate connected to the two annular plates, the outer sealing plate and the two annular plates cooperatively define the first cavity; and
an inner sealing plate connected to an inner peripheral wall of the annular plate located interiorly, the inner sealing plate and the vertical plate cooperatively defines the second cavity;
wherein the annular plate located interiorly is provided with a communication hole that communicates the first cavity and the second cavity.

19. A furnace comprising:
a furnace body;
a furnace tube arranged in the furnace body;
a flange mounting plate arranged on a rear end of the furnace body;
a furnace rear flange mounted on the flange mounting plate; and
a rear cover connected to the furnace rear flange and configured to seal the rear end of the furnace body, the rear cover provided with an air pipe that communicates with the furnace tube.

20. The furnace according to claim 19, wherein the rear cover is provided with an inserting protrusion, the air pipe is inserted into the inserting protrusion, and the inserting protrusion is inserted into the furnace tube; the rear cover is further provided with an inserting groove, the inserting groove is surrounding the inserting protrusion, and the furnace tube is inserted into the inserting groove.
